(19) United States
(12) Patent Application Publication
(10) Pub. No.: US 2024/0186462 A1
(43) Pub. Date: Jun. 6, 2024

(54) DISPLAY PANEL, FABRICATION METHOD THEREOF, AND MOBILE TERMINAL

(71) Applicant: SUZHOU CHINA STAR OPTOELECTRONICS TECHNOLOGY CO., LTD., Suzhou, Jiangsu (CN)

(72) Inventors: Lu CHEN, Suzhou, Jiangsu (CN); Qiong LIU, Suzhou, Jiangsu (CN); Junjie LI, Suzhou, Jiangsu (CN); Dan CAO, Suzhou, Jiangsu (CN)

(21) Appl. No.: 17/759,949

(22) PCT Filed: Jul. 8, 2022
(86) PCT No.: PCT/CN2022/104710

§ 371 Date: Aug. 2, 2022

(30) Foreign Application Priority Data
Jun. 24, 2022 (CN) 202210729826.6

(51) Int. Cl. H01L 33/50; H01L 25/075

(52) U.S. Cl. CPC H01L 33/502; H01L 25/0753; H01L 33/505; H01L 2933/0041

(57) ABSTRACT

The present application provides a display panel, a fabrication thereof, and a mobile terminal. The display panel includes a light-emitting substrate and a color conversion layer disposed on a light-emitting side of the light-emitting substrate, and the color conversion layer includes two protective layers and a quantum dot layer disposed between the two protective layers. The quantum dot layer includes a first conversion portion and a second conversion portion, the second conversion portion is disposed on an end face of the first conversion portion and surrounds the first conversion portion. Along a direction perpendicular to the light-emitting substrate, a thickness of the second conversion portion is greater than a thickness of the first conversion portion.

### FIELD OF INVENTION

The invention relates to the display field, and particularly to an OLED display panel, a fabrication method thereof, and a mobile terminal.

### BACKGROUND

At present, a quantum dot color conversion film is usually designed with a three-layer structure, and a middle layer is a mixed layer of quantum dot particles and an optical glue, and protective layers are provided on both sides of the middle layer.

In a production process of the color conversion film, the entire quantum dot color conversion film will be cut into pieces. When the quantum dot color conversion film is cut into small pieces, since there is no protective layer on the side wall of the film layer, a failure area will be generated on a periphery of the cut quantum dot color conversion film under actions of water and oxygen. A blue light emitted by a mini-LED light panel cannot be converted into white light when it passes through the failure area, which will lead to a blue light leakage phenomenon on an edge of the mini-LED panel, thereby affecting display effects of the mini-LED display panel.

### Technical Solution

Embodiments of the present application provide a display panel, a fabrication method thereof, and a mobile terminal to solve the technical problem of blue light leakage on the periphery of the display panel caused by the failure of the quantum dots on the periphery of the color conversion layer caused by water and oxygen erosion.

In order to solve the above technical problems, embodiments of the present invention disclose the following technical solutions:

An embodiment of the present application provides a display panel, comprising:
a light-emitting substrate, comprising a substrate and a plurality of light sources disposed on the substrate; and
a color conversion layer disposed on one side of a light-emitting surface of the light-emitting substrate, wherein the color conversion layer comprises a quantum dot layer and a protective layer disposed on both sides of the quantum dot layer,
wherein the quantum dot layer comprises a first conversion portion and a second conversion portion, the second conversion portion is disposed on an end face of the first conversion portion to surround the first conversion portion, and a thickness of the second conversion portion is greater than a thickness of the first conversion portion along a direction perpendicular to the light-emitting substrate.

In one embodiment, along a direction perpendicular to the light-emitting substrate, the thickness of the first conversion portion is a first thickness, the second conversion portion comprises a second conversion sub-portion, and a first conversion sub-portion located on a side of the conversion sub-portion away from the center of the color conversion layer, and wherein a volume of the second conversion sub-portion is greater than or equal to a volume of the second conversion sub-portion under the first thickness.

In one embodiment, the thickness of the second conversion portion is a second thickness, and a ratio of the second thickness to the first thickness is 1.3 to 2.

In one embodiment, a distance between a side surface of the second conversion portion close to the center of the color conversion layer and another side surface of the second conversion portion away from the center of the color conversion layer is greater than 1.5 mm.

In one embodiment, the second conversion portion comprises a first sub-portion and a second sub-portion, wherein a distance of the first sub-portion from a center of the color conversion layer is greater than a distance of the second sub-portion from the center of the color conversion layer along the direction perpendicular to the light-emitting substrate, and a thickness of the first sub-portion is greater than a thickness of the second sub-portion.

In one embodiment, along a direction from an edge of the color conversion layer to a center of the color conversion layer, the thickness the second conversion portion gradually decreases along a vertical direction of the light-emitting substrate.

In one embodiment, the protective layer comprises a first protective layer and a second protective layer, and the first conversion portion is level with a side surface of the second conversion portion close to the first protective layer, and a side surface of the second conversion portion toward the second protective layer is raised.

In one embodiment, the second conversion portion further comprises a third sub-portion, and the third sub-portion is located on a side of the first sub-portion away from the center of the color conversion layer, and the thickness of the third sub-portion is smaller than the thickness of the first sub-portion along the direction perpendicular to the light-emitting substrate.

In one embodiment, a thickness of the second conversion portion gradually increases first and then decrease gradually along a direction from an edge of the color conversion layer to a center of the color conversion layer.

The present application also provides a fabrication method of a display panel, comprising following steps:
providing a light-emitting substrate comprising a substrate and a plurality of light sources disposed on the substrate; and
forming a color conversion layer on a side of a light-emitting surface of the light-emitting substrate, wherein the color conversion layer comprises a quantum dot layer and two protective layers that are stacked, the quantum dot layer is disposed between the two protective layers, the quantum dot layer comprises a first conversion portion and a second conversion portion, the second conversion portion is arranged on an end face of the first conversion portion to surround the first conversion portion, and a thickness of the second conversion portion is greater than a thickness of the first conversion portion along a direction perpendicular to the light-emitting substrate.

In one embodiment, forming the color conversion layer comprises following steps:
providing a motherboard of the color conversion layer, wherein the motherboard of the color conversion layer comprises a main body portion and a cutting portion, the thickness of the quantum dot layer corresponding to the cutting portion is greater than the thickness of the quantum dot layer corresponding to the main body portion, the cutting portion comprises a plurality of first strip-shaped portions extending along a first direction and arranged in parallel to each other, and a plurality of second strip-shaped portions extending along a second direction and arranged in parallel to each other, and the first direction and the second direction is a preset angle; and
performing cutting along the cutting portion on the motherboard of the color conversion layer.

The present application also provides a mobile terminal, comprising a display panel and a terminal body, the terminal body and the display panel being combined into one body; and
wherein the display panel comprises:
a light-emitting substrate, comprising a substrate and a plurality of light sources disposed on the substrate; and
a color conversion layer disposed on one side of a light-emitting surface of the light-emitting substrate, wherein the color conversion layer comprises a quantum dot layer and a protective layer disposed on both sides of the quantum dot layer,
wherein the quantum dot layer comprises a first conversion portion and a second conversion portion, the second conversion portion is disposed on an end face of the first conversion portion to surround the first conversion portion, and a thickness of the second conversion portion is greater than a thickness of the first conversion portion along a direction perpendicular to the light-emitting substrate.

In one embodiment, along a direction perpendicular to the light-emitting substrate, the thickness of the first conversion portion is a first thickness, the second conversion portion comprises a second conversion sub-portion, and a first conversion sub-portion located on a side of the second conversion sub-portion away from the center of the color conversion layer, and wherein a volume of the second conversion sub-portion is greater than or equal to a volume of the second conversion sub-portion under the first thickness.

In one embodiment, the thickness of the second conversion portion is a second thickness, and a ratio of the second thickness to the first thickness is 1.3 to 2.

In one embodiment, a distance between a side surface of the second conversion portion close to the center of the color conversion layer and another side surface of the second conversion portion away from the center of the color conversion layer is greater than 1.5 mm.

In one embodiment, the second conversion portion comprises a first sub-portion and a second sub-portion, wherein a distance of the first sub-portion from a center of the color conversion layer is greater than a distance of the second sub-portion from the center of the color conversion layer along the direction perpendicular to the light-emitting substrate, and a thickness of the first sub-portion is greater than a thickness of the second sub-portion.

In one embodiment, along a direction from an edge of the color conversion layer to a center of the color conversion layer, the thickness the second conversion portion gradually decreases along a vertical direction of the light-emitting substrate.

In one embodiment, the protective layer comprises a first protective layer and a second protective layer, and the first conversion portion is level with a side surface of the second conversion portion close to the first protective layer, and a side surface of the second conversion portion toward the second protective layer is raised.

In one embodiment, the second conversion portion further comprises a third sub-portion, and the third sub-portion is located on a side of the first sub-portion away from the center of the color conversion layer, and the thickness of the third sub-portion is smaller than the thickness of the first sub-portion along the direction perpendicular to the light-emitting substrate.

In one embodiment, a thickness of the second conversion portion gradually increases first and then decrease gradually along a direction from an edge of the color conversion layer to a center of the color conversion layer.

One of the above technical solutions has the following advantages or beneficial effects:

By setting the display panel to comprise a light-emitting substrate and a color conversion layer disposed on a light-emitting side of the light-emitting substrate, and the color conversion layer comprises two protective layers and a quantum dot layer disposed between the two protective layers. The quantum dot layer comprises a first conversion portion and a second conversion portion, the second conversion portion is disposed on an end face of the first conversion portion and surrounds the first conversion portion. Along a direction perpendicular to the light-emitting substrate, a thickness of the second conversion portion is greater than a thickness of the first conversion portion, so that within a unit area, the number of quantum dots close to an edge is greater than the number of quantum dots in the first conversion portion per unit area, thereby avoiding the failure of the quantum dots on the edge of the color conversion layer due to water and oxygen erosion, and alleviating the problem of blue light leakage on the edge of the display panel.

### BRIEF DESCRIPTION OF DRAWINGS

To detailly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 is a schematic structural diagram of a display panel provided by an embodiment of the present application.

FIG. 2 is a schematic structural diagram of a quantum dot layer provided in an embodiment of the present application.

FIG. 3 is a schematic structural diagram of another quantum dot layer provided in an embodiment of the present application.

FIG. 4 is a schematic structural diagram of another quantum dot layer provided in an embodiment of the present application.

FIG. 5 is a schematic structural diagram of another quantum dot layer provided in an embodiment of the present application.

FIG. 6 is a schematic structural diagram of another quantum dot layer provided in an embodiment of the present application.

FIG. 7 is a perspective view of a quantum dot layer provided by an embodiment of the present application.

FIG. 8 is a schematic structural diagram of a quantum dot layer of a motherboard of a color conversion layer provided in an embodiment of the present application.

FIG. 9 is a side view of a quantum dot layer of a motherboard of a color conversion layer provided in an embodiment of the present application.

FIG. 10 is a schematic structural diagram of a color conversion layer in the prior art.

FIG. 11 is a flowchart of fabricating of a display panel provided by an embodiment of the present application.

FIG. 12 is a flowchart of fabricating a color conversion layer provided by an embodiment of the present application.

### DETAILED DESCRIPTION

The present application provides a display panel, a fabrication method of the display panel, and a mobile terminal. In order to make the purpose, technical solutions and effects of the present application clear, the present application will be further described in detail below with reference to the accompanying drawings and embodiments. It should be understood that embodiments described herein are only used to explain the present application, but not to limit the present application.

Embodiments of the present application provide a display panel, a fabrication method of the display panel, and a mobile terminal. Each of them will be described in detail below. It should be noted that the description order of the following embodiments is not intended to limit the preferred order of the embodiments.

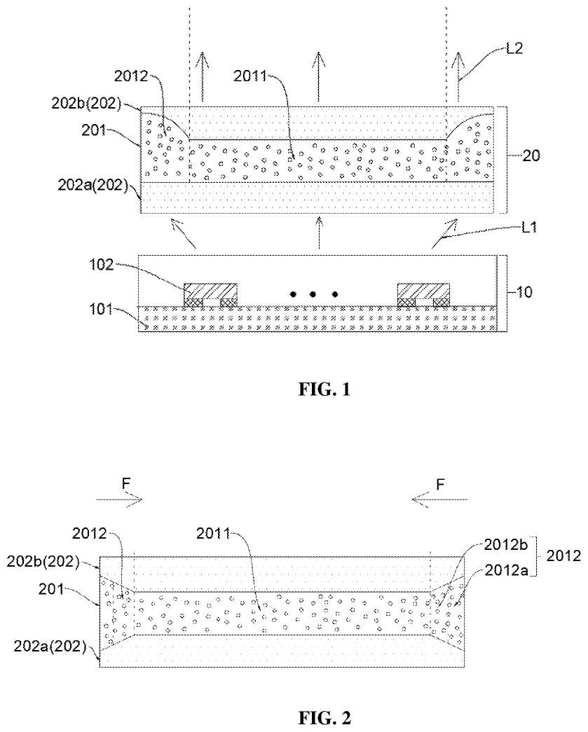

Embodiments of the present application provides a display panel as shown in FIGS. 1-9, comprising following elements:

a light-emitting substrate 10, comprising a substrate 101 and a plurality of light sources 102 disposed on the substrate 101; and

a color conversion layer 20 disposed on a side of a light-emitting surface of the light-emitting substrate 10, and the color conversion layer 20 comprises a quantum dot layer 201 and a protective layer 202 disposed on both sides of the quantum dot layer 201.

Herein, the quantum dot layer 201 comprises a first conversion portion 2011 and a second conversion portion 2012. The second conversion portion 2012 is disposed on end faces of the first conversion portion 2011 and surrounds the first conversion portion 2011. Along a direction perpendicular to the light emitting substrate 10, a thickness of the second conversion portion 2012 is greater than a thickness of the first conversion portion 2011.

It should be noted that the display panel in this application comprises a mini-LED display panel.

Specifically, as shown in FIG. 1, the light-emitting substrate 10 comprises a substrate 101 and a plurality of light sources 102 disposed on the substrate 101. The plurality of light sources 102 are arranged at intervals, and the light sources 102 may be blue light-emitting devices. For example, it can be an OLED light-emitting device or a mini-LED light-emitting device. The light source 102 emits blue light L1, and the blue light L1 undergoes color conversion through the color conversion layer 20 and is converted into white light L2 and emitted.

Specifically, the color conversion layer 20 comprises a quantum dot layer 201, and a protective layer 202 disposed on both sides of the quantum dot layer 201 toward and away from the light-emitting substrate 10 to protect the quantum dot layer 201 from being erroded by water and oxygen to improve a lifespan of quantum dots in the quantum dot layer 201.

Specifically, a material of the protective layer 202 can be silicon oxide, specifically silicon dioxide. The protective layer 202 can also be a composite film layer of silicon oxide and a high molecular polymer.

Specifically, the material of the quantum dot layer 201 comprises quantum dots and a glue material, and the quantum dots are uniformly distributed in the glue material. The quantum dots are nanoparticles with a size between 1 and 20 nanometers and comprises mixed red light quantum dots and green light quantum dots that emit red light and green lights under the irradiation of blue light L1, so that the color of the blue light L1 can be converted into white light L2 through the color conversion layer 20 to emit thereof. The glue material comprises an UV light glue but is not limited thereto.

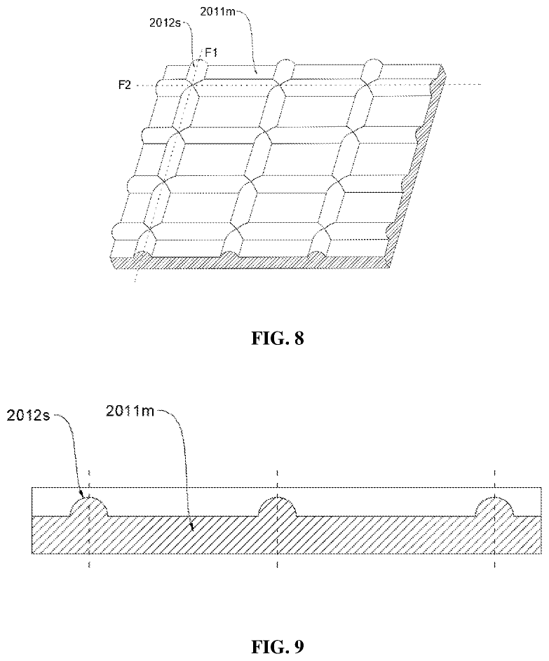

It should be noted that the color conversion layer 20 is usually obtained by cutting a mother board of the color conversion layer 20 according to a size required for the product production. The quantum dot layer 201 of a mother board of the color conversion layer 20 is shown in FIG. 8, and the quantum dot layer 201 of the color conversion layer 20 are obtained after cutting is shown in FIG. 7.

It should be noted that an exposed side surface of the quantum dot layer 201 is easily eroded by water and oxygen on a cut surface of the color conversion layer 20 obtained after cutting. An erosion direction of water and oxygen gradually approaches a center of the display panel from a periphery, and the edge portion of the quantum dot layer 201 is eroded by water and oxygen, which causes loses of color conversion ability and fails to convert the blue light L1 emitted by the blue light source 102 into white light L2, thereby resulting in the problem of blue light leakage L1 on the periphery of the display panel.

Specifically, the quantum dot layer 201 comprises a first conversion portion 2011 and a second conversion portion 2012, and the second conversion portion 2012 and the first conversion portion 2011 are an integrated structure in the actual production, and there is no gap therebetween.

Specifically, the description “the second conversion portion 2012 is disposed on an end face of the first conversion portion 2011 and surrounds the first conversion portion 2011” means that a projection of the second conversion portion 2012 along a direction perpendicular to the first conversion portion surrounds the first conversion portion 2011.

It should be noted that the second conversion portion 2012 has a corresponding depth L, and the depth L refers to a vertical distance between a side surface of the second conversion portion 2012 close to a center of the color conversion layer 20 and a side surface of the second conversion portion 2012 away from the center of the color conversion layer 20, which is shown in FIG. 4.

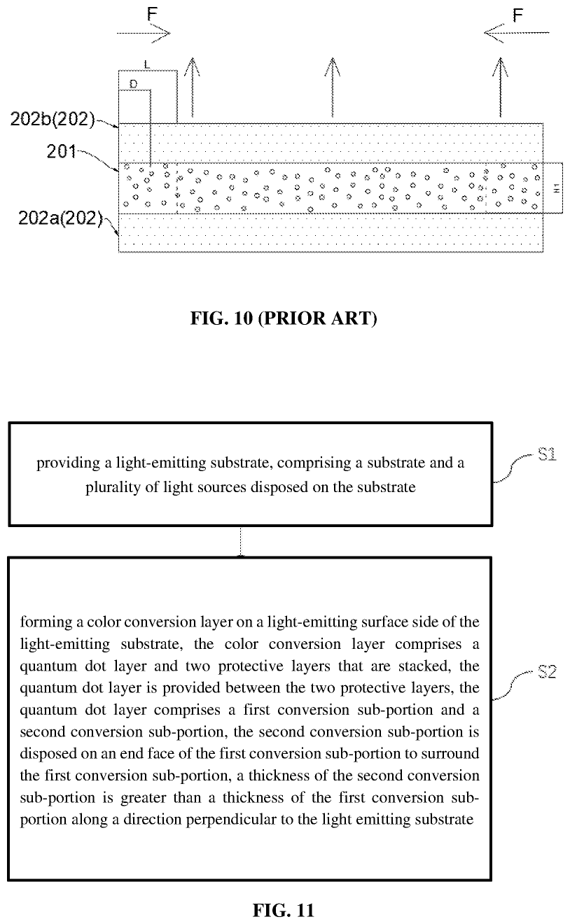

In the prior art, as shown in FIG. 10, the color conversion layer 20 has a failure depth D, and the failure depth D is obtained by an actual measurement. The failure depth D is related to the thickness of the color conversion layer 20. Under a common thickness of the display panel, a thickness of the quantum dot layer 201 is 0.3 mm, and the failure depth D is about 1.5 mm.

Specifically, the description “along a direction perpendicular to the light-emitting substrate 10, a thickness of the second conversion portion 2012 is greater than a thickness of the first conversion portion 2011” can be considered as follows.

The thickness of each portion of the second conversion portion 2012 is greater than the thickness of the first conversion portion 2011, or

the thickness of at least a portion of the second conversion portion 2012 is greater than the thickness of the first conversion portion 2011, and a volume corresponding to the depth L of the second conversion portion 2012 is greater than a volume of the second conversion portion 2012 under a unit length (e.g., 1 mm), and the volume corresponds to the depth L of the conversion sub-portion 2012 is greater than the volume corresponds to the thickness of the first conversion portion 2011.

Specifically, the thickness of the second conversion portion 2012 is set to be larger than the thickness of the second conversion portion 2012, so that a volume of the quantum dot near the periphery of the quantum dot layer 201 is larger, even if some quantum dots on the periphery fail, there are still some quantum dots can be used for photo-conversion in the second conversion portion 2012, so as to realize the conversion of blue light L1 on the periphery into white light L2 and alleviate the problem of blue light leakage L1 on the periphery of the display panel in the prior art, and improve a white light conversion rate of the display panel structure.

It should be noted that, referring to FIG. 10 and FIG. 4, FIG. 10 is a schematic structural diagram of a color conversion layer 20 in the prior art, and thicknesses of the quantum dot layers 201 is the same everywhere, and FIG. 4 is a schematic structural diagram of a color conversion layer 20 according to an embodiment of the present application, wherein the quantum dot layer 201 comprises a first conversion portion 2011 and a second conversion portion 2012. By comparison, it can be seen that an exposed area of a side surface of the quantum dot layer 201 in the embodiment shown in FIG. 4 is greater than that disclosed in the prior art (see FIG. 10). According to the theory, a greater amount of the quantum dots in the quantum dot layer 201 corresponding to this embodiment is eroded by water and oxygen, and the portion of the quantum dots that fail will increase. In fact, in this embodiment, the amount of quantum dots in the second conversion portion 2012 can offset the portion of the water-oxygen erosion failure relative to the quantity of quantum dots in the corresponding position in the prior art, and there are more quantum dots that can realize normal conversion at the same time, so the technical solution of this embodiment can be used to effectively enhance the white light conversion rate of the color conversion layer 20.

It can be understood that by setting the display panel to comprise a light-emitting substrate 10 and a color conversion layer 20 disposed on a light-emitting side of the light-emitting substrate 10, and the color conversion layer 20 comprises two protective layers 202 and a quantum dot layer 201 disposed between the two protective layers 202. The quantum dot layer 201 comprises a first conversion portion 2011 and a second conversion portion 2012, the second conversion portion 2012 is disposed on an end face of the first conversion portion 2011 and surrounds the first conversion portion 2011. Along a direction perpendicular to the light-emitting substrate 10, a thickness of the second conversion portion 2012 is greater than a thickness of the first conversion portion 2011, so that within a unit area, the number of quantum dots close to an edge is greater than the number of quantum dots in the first conversion portion 2011 per unit area, thereby avoiding the failure of the quantum dots on the edge of the color conversion layer 20 due to water and oxygen erosion, and alleviating the problem of blue light leakage L1 on the edge of the display panel.

In one embodiment, as shown in FIG. 4, along a direction perpendicular to the light-emitting substrate 10, the thickness of the first conversion portion 2011 is a first thickness H1, and the second conversion portion 2012 comprises a second conversion sub-portion 2012A2 and a first conversion sub-portion 2012A1 located on the side of the second conversion portion 2012A2 away from the center of the color conversion layer 20. Herein, a volume of the second conversion sub-portion 2012A2 is greater than or equal to the volume of the second conversion portion 2012 under the first thickness H1.

It should be noted that the quantum dots in the second conversion sub-portion 2012A2 and the first conversion sub-portion 2012A1 can normally perform white light conversion after the product is produced and not eroded by water and oxygen.

It should be noted that the first conversion sub-portion 2012A1 is located outside the second conversion portion 2012 (i.e., away from the center of the color conversion layer 20). After a period of use, a portion of the quantum dots in the first conversion sub-portion 2012A1 cannot perform color conversion, and the overall white light conversion rate is low, which does not meet the actual production requirements.

It should be noted that the second conversion sub-portion 2012A2 is located inside the second conversion portion 2012 (i.e., close to the center of the color conversion layer 20). After a period of use, the second conversion sub-portion 2012A2 also has a portion of quantum dots cannot perform color conversion, but the overall white light conversion rate still meets production requirements.

Specifically, the description “the volume of the second conversion sub-portion 2012A2 is greater than or equal to the volume of the second conversion portion 2012 corresponding to the first thickness H1” means that in one embodiment as shown in FIG. 4, the volume of the second conversion sub-portion 2012A2 capable of effectively converting white light in the conversion sub-portion 2012 is greater than or equal to the volume of the second conversion portion 2012 corresponding to the first thickness H1 under the depth L, so that the white light conversion rate of the second conversion portion 2012 is at least equal to the white light conversion rate of an area in the first conversion portion 2011 that equals to an orthographic projection area of the second conversion portion 2012 along a direction along the light emitting substrate 10 (i.e., the light-emitting surface).

It can be understood that by adopting this technical solution, the white light conversion rate of the second conversion portion 2012 can be the same as or higher than the white light conversion rate of the first conversion portion 2011, which solves the problem of blue light L1 light leakage on the periphery of the display panel.

In one embodiment, the thickness of the second conversion portion 2012 is a second thickness H2, and a ratio of the second thickness H2 to the first thickness H1 is 1.3-2.

Specifically, the thickness of the second conversion portion 2012 is the second thickness H2. In a specific example, as shown in FIG. 4, the second conversion portion 2012 has a plurality of thicknesses, and the second thickness H2 is defined as the maximum value of the plurality of thicknesses in the second conversion portion 2012.

Specifically, as shown in FIG. 4, the first conversion portion 2011 has a first thickness H1, the maximum thickness of the second conversion portion 2012 is H2, and the ratio of the second thickness H2 to the first thickness H1 is controlled as any value of 1.3, 1.4, 1.5, 1.6, 1.7, 1.8, 1.9, and 2.0, which can be adjusted according to actual production conditions.

It can be understood that by further limiting the thickness of the second conversion portion 2012, the overall thickness of the display panel can be reduced and user experience can be improved on the basis of ensuring that the periphery of the display panel does not leak blue light L1.

In one embodiment, between a side of the second conversion portion 2012 close to the center of the color conversion layer 20 and the other side of the second conversion portion 2012 away from the center of the color conversion layer 20 The distance is greater than 1.5 mm.

Specifically, the second conversion portion 2012 has a corresponding depth L, and the depth L refers to a vertical distance between a side surface of the second conversion portion 2012 close to the center of the color conversion layer 20 to a side surface of the second conversion portion 2012 away from the center of the color conversion layer 20, which is shown in FIG. 4.

Specifically, as shown in FIG. 10, the color conversion layer 20 has a failure depth D, and the failure depth D is obtained through an actual measurement. The failure depth D is related to the thickness of the color conversion layer 20, but in a display panel having the quantum dot layer 201 of a thickness of 0.3 mm, the failure depth D is about 1.5 mm.

It can be understood that, by setting the depth L of the second conversion portion 2012 to be greater than 1.5 mm, the display panel has a thinner thickness while ensuring that the side edges do not leak blue light L1, thereby improving the user experience.

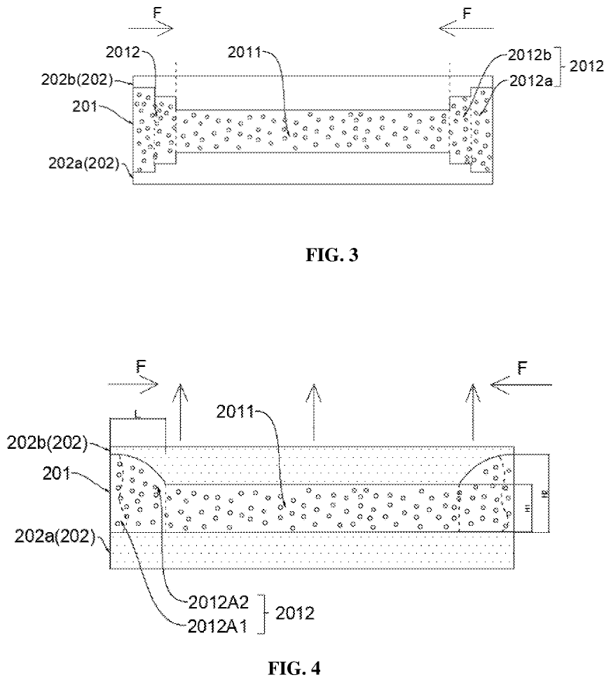

In one embodiment, as shown in FIG. 2 and FIG. 3, the second conversion portion 2012 comprises a first sub-portion 2012a and a second sub-portion 2012b. A distance of the first sub-portion 2012a to the center of the second sub-portion 2012b of the second sub-portion 20 is greater than a distance of the second sub-portion 20 to the center of the color conversion layer 20. A thickness of the first sub-portion 2012a is greater than a thickness of the second sub-portion 2012a along the direction perpendicular to the light-emitting substrate 10.

Specifically, in an example, as shown in FIG. 2, the first sub-portion 2012a and the second sub-portion 2012b are an integrally formed structure, and a thickness of the first sub-portion 2012a gradually decreases and a thickness of the second sub-portion 2012b gradually decreases along a direction F that from an edge of the quantum dot layer 201 to the color conversion layer 20.

Specifically, the two side surfaces of the second sub-portion 2012b close to or away from the light-emitting substrate 10 may be curved surfaces (as shown in the upper surface in FIG. 4), inclined surfaces (as shown in FIG. 2), or step-like curved surfaces (as shown in FIG. 3), and the shape is not limited thereto.

Specifically, in an example, as shown in FIG. 3, the first sub-portion 2012a and the second sub-portion 2012b are an integrally formed structure, and the thicknesses over the first sub-portion 2012a are equal everywhere, so the thickness of the second sub-portion 2012b is the same at various places, and the thickness of the first sub-portion 2012a is greater than the thickness of the second sub-portion 2012b.

It can be understood that, in the direction F from the edge of the quantum dot layer 201 to the center of the color conversion layer 20, the thickness of the second conversion layer generally decreases, so that the chromaticity of the display panel increases from the edge to the center of the color conversion layer 20. The transition from the center to the center is uniform, which effectively improves the display effect of the display panel.

In one embodiment, as shown in FIG. 2 and FIG. 4, along the direction F from the edge of the color conversion layer 20 to the center of the color conversion layer 20, the thickness of the second conversion portion 2012 gradually decreases along a direction perpendicular to the light-emitting substrate 10.

Specifically, the two side surfaces of the second sub-portion 2012b close to or away from the light-emitting substrate 10 may be curved surfaces (the upper surface in FIG. 4) or inclined surfaces (as shown in FIG. 2).

It can be understood that the thickness of the second conversion layer gradually decreases along the direction F from the edge of the quantum dot layer 201 to the center of the color conversion layer 20, so the transition of the chromaticity of the display panel is uniform along a direction from the edge to the center, which effectively improves the display effect of the display panel.

In one embodiment, the protective layer 202 comprises a first protective layer 202a and a second protective layer 202b, the first conversion portion 2011 is level with a side surface of the second conversion portion 2012 close to the first protective layer 202a, and the second conversion portion 2012 protrudes toward one side surface of the second protective layer 202b.

Specifically, as shown in FIG. 1 and FIG. 4, the first conversion portion 2011 and a side surface of the second conversion portion 2012 facing the light-emitting substrate 10 are disposed on the same plane, and the second conversion portion 2012 relatively protrudes over the light-emitting surface of the display panel than the first conversion portion 2011.

Specifically, the shape of the protrusion is not limited, and its cross section may be fan-shaped, step-shaped or wedge-shaped.

Specifically, the color conversion layer 20 is obtained by cutting a motherboard of the color conversion layer 20. By setting the first conversion portion 2011 being leveled with a side surface of the second conversion portion 2012 close to the first protective layer 202a, it is possible to avoid an etching step for additionally forming a concave structure after the first conversion portion 2011 is formed.

It can be understood that the first conversion portion 2011 is leveled with a side surface of and the second conversion portion 2012 close to the first protective layer 202a, and the second conversion portion 2012 facing a side surface of the second protective layer 202b is raised, which can reduce the production cost of the color conversion layer 20 while solving the problem of blue light leakage L1 on the edge of the display panel.

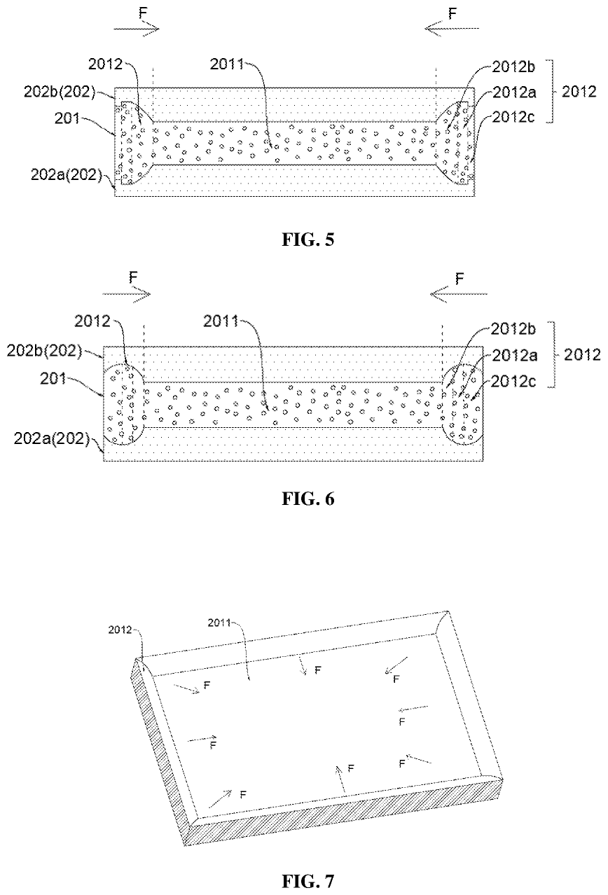

In one embodiment, as shown in FIG. 5, the second conversion portion 2012 further comprises a third sub-portion 2012c, and the third sub-portion 2012c is located on a side surface of the light emitting substrate 10 away from the center of the first sub-portion 2012a away from the color conversion layer 20. The thickness of the third sub-portion 2012c is smaller than the thickness of the first sub-portion 2012a along the direction perpendicular to the light-emitting substrate 10.

Specifically, in the prior art, the blue light L1 leakages on the periphery of the display panel is due to failures of the quantum dots being eroded by water and oxygen since the periphery of the quantum dot layer 201 is exposed. Therefore, the second conversion portion 2012 comprises the first sub-portion 2012a, the second sub-portion 2012b and the third sub-portion 2012c, and the thickness of the third sub-portion 2012c is smaller than the thickness of the first sub-portion 2012a, so that the amount of the quantum dots being exposed on the end face is smaller than that of the above-mentioned embodiment, which further reduces the quantity of the failure of quantum dots used in the second conversion portion 2012 as a whole can be reduced, and the production cost can be reduced.

Specifically, the thicknesses over variation portions of the third sub-portions 2012c may be the same (as shown in FIG. 5) or different (as shown in FIG. 6).

It can be understood that by arranging the third sub-portion 2012c and make the thickness of the third sub-portion 2012c smaller than the thickness of the first sub-portion 2012a, the exposed area of the end face of the second conversion section 2012 can be reduced, and the amount of failure of quantum dots can be reduced, so that the amount of quantum dots used in the second conversion portion 2012 is reduced to a certain extent, and the production cost of the color conversion film layer of the embodiment of the present application can be effectively reduced.

In one embodiment, as shown in FIG. 6, the thickness of the second conversion portion 2012 along a direction perpendicular to the light-emitting substrate 10 firstly increases and then decreases gradually along the direction F from the edge of the color conversion layer 20 to the center of the color conversion layer 20.

Specifically, the side surfaces of the third sub-portion 2012c, the first sub-portion 2012a, and the second sub-portion 2012b facing or away from the light-emitting substrate 10 are arranged to be smooth curved surfaces.

It can be understood that, by disposing the third sub-portion 2012c, the exposed area of the end face of the second conversion section 2012 is reduced, the amount of failure of the quantum dot is effectively reduced, so that the quantum dots of the second conversion section 2012 are reduced to a certain extent. The usage amount can effectively reduce the production cost of the color conversion film layer of the embodiments of the present application, and at the same time, the third sub-portion 2012c, the first sub-portion 2012a and the second sub-portion 2012b are arranged to face or face away from the light-emitting substrate 10. The side surface of the display panel is a smooth curved surface, which can simplify the production steps on the one hand and make the chromaticity transition of the display panel from the edge to the center more uniform and improve the display effect of the display panel.

The present application also provides a fabrication method of a display panel, as shown in FIG. 11, comprising the following steps:

Step S1: providing a light-emitting substrate 10, comprising a substrate 101 and a plurality of light sources 102 disposed on the substrate 101.

Step S2: forming a color conversion layer 20 on a light-emitting surface side of the light-emitting substrate 10. The color conversion layer 20 comprises a quantum dot layer 201 and two protective layers 202 that are stacked. The quantum dot layer 201 is provided between the two protective layers 202. The quantum dot layer 201 comprises a first conversion portion 2011 and a second conversion portion 2012. The second conversion portion 2012 is disposed on an end face of the first conversion portion 2011 to surround the first conversion portion 2011. A thickness of the second conversion portion 2012 is greater than a thickness of the first conversion portion 2011 along a direction perpendicular to the light emitting substrate 10.

Specifically, materials and structures of the light-emitting substrate 10, the protective layer 202, and the quantum dot layer 201 can be found in the above-mentioned embodiments, which will not be repeated here.

It can be understood that, by setting the display panel to comprise a light-emitting substrate 10 and a color conversion layer 20 disposed on the light-emitting side of the light-emitting substrate 10, and the color conversion layer 20 comprising a quantum dot layer 201 and a protective layer 202. The dot layer 201 comprises a first conversion portion 2011 and a second conversion portion 2012, the second conversion portion 2012 is disposed on the end face of the first conversion portion 2011 to surround the first conversion portion 2011. The thickness of the second conversion portion 2012 is greater than the thickness of the first conversion portion 2011 along a direction perpendicular to the light-emitting substrate, so that in a unit area, the number of quantum dots in the second conversion portion 2012 near the edge is larger than that of the first conversion portion, so as to avoid the problem that the edge of the color conversion layer 20 will fail due to water and oxygen erosion, and the blue light L1 will leak from the edge.

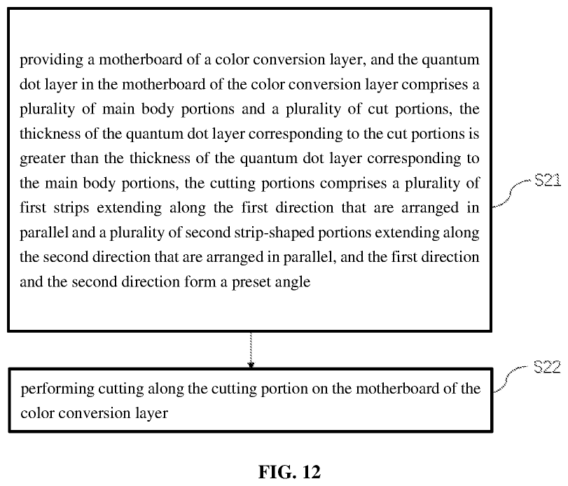

In one embodiment, as shown in FIG. 8 and FIG. 12, forming the color conversion layer 20 comprising following steps.

Step S21: providing a motherboard of a color conversion layer 20, and the quantum dot layer 201 in the motherboard of the color conversion layer 20 comprises a plurality of main body portions 2011m and a plurality of cut portions 2012s. The thickness of the quantum dot layer 201 corresponding to the cut portions 2012s is greater than the thickness of the quantum dot layer 201 corresponding to the main body portions 2011m. The cutting portions 2012s comprises a plurality of first strips extending along the first direction F1 that are arranged in parallel and a plurality of second strip-shaped portions extending along the second direction F2 that are arranged in parallel, and the first direction F1 and the second direction F2 form a preset angle.

Specifically, the preset included angle is 90°.

Step S22: performing cutting along the cutting portion 2012s on the motherboard of the color conversion layer 20.

Specifically, the fabrication method of the quantum dot layer 201 in the motherboard of the color conversion layer 20 is a layered coating. First, a layer of quantum dot glue with a uniform thickness is applied. After the quantum dot glue is cured, a second coating is performed on the corresponding cutting line to form a plurality of first strip-shaped portions and a plurality of second strip-shaped portions; and

while cutting, as shown in FIG. 8 and FIG. 9, along the first direction F1 and the second direction F2, the first strip portions and the second strip portions are cut at the center position to obtain the color conversion film layer of the embodiments of the present application.

The present application further provides a mobile terminal, comprising the display panel and a terminal body according to any one of the above embodiments and the terminal body and the display panel are combined into one body.

Specifically, mobile terminals comprises but are not limited to the following types: mobile phones, watches, wristbands, TVs or other wearable display or touch electronic devices, as well as flexible smart phones, tablet computers, notebook computers, desktop monitors, TVs Machines, smart glasses, smart watches, ATM machines, digital cameras, on-board displays, medical displays, industrial control displays, electronic paper books, electrophoretic display devices, game consoles, transparent displays, double-sided displays, naked-eye 3D displays, mirror display devices, semi-reflective and semi-transflective display devices, etc.

In summary, in the present application, the display panel comprises a light-emitting substrate 10 and a color conversion layer 20 disposed on the light-emitting side of the light-emitting substrate 10. The color conversion layer 20 comprises a quantum dot layer 201 and a plurality of protective layers 202. The dot layer 201 comprises a first conversion portion 2011 and a second conversion portion 2012, the second conversion portion 2012 is disposed on the end face of the first conversion portion 2011 to surround the first conversion portion 2011 The thickness of the second conversion portion 2012 is greater than the thickness of the first conversion portion 2011 along a direction perpendicular to the light-emitting substrate 10, so that in a unit area, the number of quantum dots in the second conversion portion 2012 near the edge is larger than that of the first conversion portion in a unit area. The number of quantum dots in the portion 2011 is reduced, so as to avoid the problem that the edge of the color conversion layer 20 will fail due to water and oxygen erosion, and the blue light L1 will leak from the edge.

A display panel, a fabrication method of a display panel, and a mobile terminal provided by the embodiments of the present application have been described in detail above. While the present disclosure has been described with the above preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. A display panel, comprising:
a light-emitting substrate, comprising a substrate and a plurality of light sources disposed on the substrate; and
a color conversion layer disposed on a side of a light-emitting surface of the light-emitting substrate, wherein the color conversion layer comprises a quantum dot layer and a protective layer disposed on both sides of the quantum dot layer,
wherein the quantum dot layer comprises a first conversion portion and a second conversion portion, the second conversion portion is disposed on an end face of the first conversion portion to surround the first conversion portion, and a thickness of the second conversion portion is greater than a thickness of the first conversion portion along a direction perpendicular to the light-emitting substrate.

2. The display panel according to claim 1, wherein, along a direction perpendicular to the light-emitting substrate, the thickness of the first conversion portion is a first thickness, the second conversion portion comprises a second conversion sub-portion, and a first conversion sub-portion located on a side of the second conversion sub-portion away from the center of the color conversion layer, and wherein a volume of the second conversion sub-portion is greater than or equal to a volume of the second conversion sub-portion conversion sub-portion under the first thickness.

3. The display panel of claim 2, wherein the thickness of the second conversion portion is a second thickness, and a ratio of the second thickness to the first thickness is 1.3 to 2.

4. The display panel of claim 1, wherein a distance between a side surface of the second conversion portion close to the center of the color conversion layer and another side surface of the second conversion portion away from the center of the color conversion layer is greater than 1.5 mm.

5. The display panel of claim 1, wherein the second conversion portion comprises a first sub-portion and a second sub-portion, wherein a distance of the first sub-portion from a center of the color conversion layer is greater than a distance of the second sub-portion from the center of the color conversion layer along the direction perpendicular to the light-emitting substrate, and a thickness of the first sub-portion is greater than a thickness of the second sub-portion.

6. The display panel of claim 5, wherein, along a direction from an edge of the color conversion layer to a center of the color conversion layer, the thickness the second conversion portion gradually decreases along a vertical direction of the light-emitting substrate.

7. The display panel of claim 6, wherein the protective layer comprises a first protective layer and a second protective layer, and the first conversion portion is level with a side surface of the second conversion portion close to the first protective layer, and a side surface of the second conversion portion toward the second protective layer is raised.

8. The display panel of claim 5, wherein the second conversion portion further comprises a third sub-portion, and the third sub-portion is located on a side of the first sub-portion away from the center of the color conversion layer, and the thickness of the third sub-portion is smaller than the thickness of the first sub-portion along the direction perpendicular to the light-emitting substrate.

9. The display panel of claim 8, wherein, a thickness of the second conversion portion gradually increases first and then decrease gradually along a direction from an edge of the color conversion layer to a center of the color conversion layer.

10. A fabrication method of a display panel, comprising following steps:
providing a light-emitting substrate comprising a substrate and a plurality of light sources disposed on the substrate; and
forming a color conversion layer on a side of a light-emitting surface of the light-emitting substrate, wherein the color conversion layer comprises a quantum dot layer and two protective layers that are stacked, the quantum dot layer is disposed between the two protective layers, the quantum dot layer comprises a first conversion portion and a second conversion portion, the second conversion portion is arranged on an end face of the first conversion portion to surround the first conversion portion, and a thickness of the second conversion portion is greater than a thickness of the first conversion portion along a direction perpendicular to the light-emitting substrate.

11. The fabrication method of the display panel according to claim 10, wherein forming the color conversion layer comprises following steps:
providing a motherboard of the color conversion layer, wherein the motherboard of the color conversion layer comprises a main body portion and a cutting portion, the thickness of the quantum dot layer corresponding to the cutting portion is greater than the thickness of the quantum dot layer corresponding to the main body portion, the cutting portion comprises a plurality of first strip-shaped portions extending along a first direction and arranged in parallel to each other, and a plurality of second strip-shaped portions extending along a second direction and arranged in parallel to each other, and the first direction and the second direction is a preset angle; and
performing cutting along the cutting portion on the motherboard of the color conversion layer.

12. A mobile terminal, comprising a display panel and a terminal body, the terminal body and the display panel being combined into one body; and
wherein the display panel comprises:
a light-emitting substrate, comprising a substrate and a plurality of light sources disposed on the substrate; and
a color conversion layer disposed on one side of a light-emitting surface of the light-emitting substrate, wherein the color conversion layer comprises a quantum dot layer and a protective layer disposed on both sides of the quantum dot layer,
wherein the quantum dot layer comprises a first conversion portion and a second conversion portion, the second conversion portion is disposed on an end face of the first conversion portion to surround the first conversion portion, and a thickness of the second conversion portion is greater than a thickness of the first conversion portion along a direction perpendicular to the light-emitting substrate.

13. The mobile terminal according to claim 12, wherein, along a direction perpendicular to the light-emitting substrate, the thickness of the first conversion portion is a first thickness, the second conversion portion comprises a second conversion sub-portion, and a first conversion sub-portion located on a side of the second conversion sub-portion away from the center of the color conversion layer, and wherein a volume of the second conversion sub-portion is greater than or equal to a volume of the second conversion sub-portion under the first thickness.

14. The mobile terminal of claim 13, wherein the thickness of the second conversion portion is a second thickness, and a ratio of the second thickness to the first thickness is 1.3 to 2.

15. The mobile terminal of claim 12, wherein a distance between a side surface of the second conversion portion close to the center of the color conversion layer and another side surface of the second conversion portion away from the center of the color conversion layer is greater than 1.5 mm.

16. The mobile terminal of claim 12, wherein the second conversion portion comprises a first sub-portion and a second sub-portion, wherein a distance of the first sub-portion from a center of the color conversion layer is greater than a distance of the second sub-portion from the center of the color conversion layer along the direction perpendicular to the light-emitting substrate, and a thickness of the first sub-portion is greater than a thickness of the second sub-portion.

17. The mobile terminal of claim 16, wherein, along a direction from an edge of the color conversion layer to a center of the color conversion layer, the thickness the second conversion portion gradually decreases along a vertical direction of the light-emitting substrate.

18. The mobile terminal of claim 17, wherein the protective layer comprises a first protective layer and a second protective layer, and the first conversion portion is level with a side surface of the second conversion portion close to the first protective layer, and a side surface of the second conversion portion toward the second protective layer is raised.

19. The mobile terminal of claim 16, wherein the second conversion portion further comprises a third sub-portion, and the third sub-portion is located on a side of the first sub-portion away from the center of the color conversion layer, and the thickness of the third sub-portion is smaller than the thickness of the first sub-portion along the direction perpendicular to the light-emitting substrate.

20. The mobile terminal of claim 19, wherein, a thickness of the second conversion portion gradually increases first and then decrease gradually along a direction from an edge of the color conversion layer to a center of the color conversion layer.
